(19) United States
(12) Patent Application Publication
(10) Pub. No.: US 2025/0372417 A1
(43) Pub. Date: Dec. 4, 2025

(54) WAFER TEMPERATURE CONTROL DEVICE, CONTROL METHOD FOR WAFER TEMPERATURE CONTROL DEVICE, AND PROGRAM FOR WAFER TEMPERATURE CONTROL DEVICE

(71) Applicant: HORIBA STEC, Co., Ltd., Kyoto-shi, Kyoto (JP)

(72) Inventors: Kotaro TAKIJIRI, Kyoto-shi (JP); Daisuke HAYASHI, Kyoto-shi (JP)

(21) Appl. No.: 18/681,369

(22) PCT Filed: Aug. 2, 2022
(86) PCT No.: PCT/JP2022/029650

§ 371 Date: Mar. 13, 2025

(30) Foreign Application Priority Data
Aug. 6, 2021 (JP) 2021-130031

(51) Int. Cl. H01L 21/67; H01L 21/687

(52) U.S. Cl. CPC H01L 21/67248; H01L 21/68785

(57) ABSTRACT

In order to provide a wafer temperature control device capable of estimating a wafer temperature with sufficient accuracy and controlling the wafer temperature to a target temperature even when a cooling operation amount input to a cooler is changed, a heater that heats a wafer according to an input heating operation amount, a cooler that cools the wafer [W] according to an input cooling operation amount, a vicinity temperature measuring instrument that measures a vicinity temperature of the wafer, a temperature estimation observer that estimates the wafer temperature on a basis of the vicinity temperature measured by the vicinity temperature measuring instrument, and the cooling operation amount input to the cooler or the cooling amount output from the cooler, and a temperature controller that controls the cooling operation amount so as to reduce a temperature deviation between a set temperature and the estimated wafer temperature are provided.

### TECHNICAL FIELD

The present invention relates to a wafer temperature control device that controls the temperature of a wafer.

### BACKGROUND ART

In a semiconductor manufacturing process, among various processes performed on a wafer accommodated in a chamber, there is a process of controlling the temperature of the wafer to a predetermined target temperature.

For example, a wafer temperature control device described in Patent Literature 1 includes a stage including a cooling mechanism that cools a wafer placed in a chamber and a heating mechanism that heats the wafer. The stage is formed of a light-transmissive member, and a refrigerant flow path through which the refrigerant flows is formed inside the stage.

The cooling mechanism includes a chiller connected to a refrigerant flow path in the stage outside the stage, and for example, the supply of the refrigerant is switched by controlling an on-off valve. On the other hand, the heating mechanism includes a large number of LEDs provided on the side opposite to the wafer placement surface of the stage. The light emitted from each LED is configured to be emitted to the back surface of the wafer after passing through the stage. In addition, the amount of light emitted from each LED is controlled such that the temperature of the wafer becomes the target temperature.

In addition, it is difficult to actually measure the temperature of the wafer itself accommodated in the chamber due to various technical restrictions. Therefore, in Patent Literature 1, a temperature sensor is provided in a stage, a temperature of a portion near a wafer is measured, and a temperature of an electronic device formed on the wafer is estimated by an observer. Then, a current value corresponding to the temperature of the electronic device estimated by the observer is supplied to the LED, and the heating amount is controlled.

By the way, in a process using plasma, since gas molecules ionized by the plasma are caused to collide with the wafer, the temperature of the wafer increases. For this reason, a method of directly supplying a gas such as He to the back surface of the wafer and cooling the wafer is adopted. There is also a cooling only process in which heating is not performed.

However, in such an application, since the observer disclosed in Patent Literature 1 does not use the cooling amount or the cooling operation amount as an input parameter in the first place, it is difficult to estimate the wafer temperature with sufficient accuracy and control the wafer temperature to be constant at the target temperature.

### CITATION LIST

### Patent Literature

Patent Literature 1: JP 2021-19066 A

### SUMMARY OF INVENTION

### Technical Problem

The present invention has been made in view of the above-described problems, and an object thereof is to provide a wafer temperature control device capable of estimating a wafer temperature with sufficient accuracy and controlling the wafer temperature to a target temperature even when a cooling operation amount input to a cooler is changed.

### Solution to Problem

That is, a wafer temperature control device according to the present invention includes: a heater that heats a wafer according to an input heating operation amount;
a cooler that cools the wafer according to an input cooling operation amount; a vicinity temperature measuring instrument that measures a vicinity temperature of the wafer; a temperature estimation observer that estimates a wafer temperature on the basis of the vicinity temperature measured by the vicinity temperature measuring instrument and a cooling operation amount input to the cooler or a cooling amount output from the cooler; and a temperature controller that controls the cooling operation amount so as to reduce a temperature deviation between a set temperature and the estimated wafer temperature.

A control method for a wafer temperature control device according to the present invention including a heater that heats a wafer according to an input heating operation amount and a cooler that cools the wafer according to an input cooling operation amount, the control method including:
measuring a vicinity temperature of the wafer; estimating a wafer temperature on a basis of the vicinity temperature measured by the vicinity temperature measuring instrument and a cooling operation amount input to the cooler or a cooling amount output from the cooler; and controlling the cooling operation amount so as to reduce a temperature deviation between a set temperature and the estimated wafer temperature.

With such a configuration, even when the cooling operation amount is changed, the wafer temperature can be accurately estimated based on the vicinity temperature. As a result, even if the wafer temperature cannot be actually measured, the wafer temperature can be kept at the set temperature.

In order to improve the estimation accuracy of the wafer temperature by correcting the estimation error of the wafer temperature caused by the deviation of the initial temperature, it is sufficient that the temperature estimation observer includes: a temperature estimation model that is a state space model using the wafer temperature and the vicinity temperature as output variables; a vicinity temperature output unit that outputs the vicinity temperature estimated based on the temperature estimation model; a wafer temperature output unit that outputs the wafer temperature estimated based on the temperature estimation model; and an observer gain, and a value obtained by multiplying a deviation between an estimated value of the vicinity temperature output from the vicinity temperature output unit and a measured value of a vicinity temperature output from the vicinity temperature measuring instrument or a value calculated from the deviation by the observer gain is fed back into the temperature estimation model.

For example, in order to make it possible to correct a state in which a wafer temperature estimated due to an influence of a disturbance is kept deviated from an actual temperature even when the disturbance is input into a wafer temperature control device and to further improve robustness as a control system, it is sufficient that the temperature estimation observer further includes an observer integrator that integrates a deviation between an estimated value of the vicinity temperature output from the vicinity temperature output unit and a measured value of the vicinity temperature output from the vicinity temperature measuring instrument, and a value obtained by multiplying an integrated value output from the observer integrator by the observer gain is fed back into the temperature estimation model.

For example, as a configuration example suitable for heating or cooling the wafer accommodated in the chamber, a plate on which the wafer is placed is further provided, the heater is configured to heat the plate, and the cooler is configured to cool the plate.

As a specific aspect of the cooler, the cooler includes a refrigerant flow path and a refrigerant control unit that controls a flow of a refrigerant flowing in the refrigerant flow path, and the cooling operation amount is a cooling amount or a target refrigerant flow rate of the wafer.

In order to accurately simulate the cooling amount of the wafer by the cooler and improve the final estimation accuracy of the wafer temperature, it is sufficient that the temperature estimation model is a state space model in which a heating amount by the heater and a cooling amount by the cooler are input variables and the wafer temperature and the vicinity temperature are state variables, and
the cooling amount is calculated based on a difference between the wafer temperature and the vicinity temperature and a heat transfer coefficient between the wafer and the plate.

In order to accurately simulate the heat transfer from the wafer to the plate, it is sufficient that heat transfer gas is supplied between the wafer and the plate at a predetermined pressure, and the heat transfer coefficient is set based on the pressure of the heat transfer gas.

For example, in order to easily maintain the temperature of the wafer at a constant value at a high temperature while simplifying the control input, it is sufficient that the heating operation amount is set to a constant value.

In order to cause the wafer temperature to continue to coincide with the set temperature at each time by controlling not only the wafer temperature that is a final control target but also each state variable to an appropriate value, it is sufficient that the temperature controller is configured such that a state variable vector estimated by the temperature estimation observer is fed back.

For example, in order to enable the temperature estimation observer to estimate the wafer temperature in consideration of the influence of the heating to the wafer or the heat dissipation from the wafer by the gas present in the chamber to further improve the estimation accuracy, it is sufficient that the temperature estimation observer further includes a gas temperature measuring instrument that measures the temperature of the gas present near the upper side of the wafer, and the temperature estimation observer estimates the wafer temperature on the basis of the vicinity temperature measured by the vicinity temperature measuring instrument, a cooling operation amount input to the cooler or a cooling amount output from the cooler, and the gas temperature measured by the gas temperature measuring instrument.

In order to achieve temperature control performance equivalent to that of the wafer temperature control device according to the present invention by updating a program in an existing wafer temperature control device, it is sufficient to use a program for a wafer temperature control device, the program being used in a wafer temperature control device including a heater that heats the wafer according to an input heating operation amount and a cooler that cools the wafer according to an input cooling operation amount, the program causing a computer to exhibit the functions as: a vicinity temperature measuring instrument that measures a vicinity temperature of the wafer; a temperature estimation observer that estimates a wafer temperature on the basis of the vicinity temperature measured by the vicinity temperature measuring instrument, and a cooling operation amount input to the cooler or a cooling amount output from the cooler; and a temperature controller that controls the cooling operation amount so as to reduce a temperature deviation between a set temperature and the estimated wafer temperature.

Note that the program for the wafer temperature control device may be distributed electronically or may be recorded in a program recording medium such as a CD, a DVD, or a flash memory.

### Advantageous Effects of Invention

As described above, the wafer temperature control device according to the present invention can accurately estimate the wafer temperature that is difficult to directly measure even when the cooling operation amount is changed. In addition, since the cooling operation amount is controlled based on the temperature deviation between the wafer temperature estimated with high accuracy and the set temperature, for example, the control accuracy of the wafer temperature can be improved as compared with the related art.

### BRIEF DESCRIPTION OF DRAWINGS

FIG. 1 is a schematic perspective view of a wafer temperature control device according to a first embodiment of the present invention.

FIG. 2 is a schematic configuration diagram of the wafer temperature control device in the first embodiment.

FIG. 3 is a schematic diagram of the wafer temperature control device in the first embodiment expressed by a state equation.

FIG. 4 is a functional block diagram illustrating the wafer temperature control device in the first embodiment.

FIG. 5 is a graph showing the relationship between a pressure of heat transfer gas supplied between a wafer and a plate and a heat transfer coefficient between the wafer and the plate in the first embodiment.

FIG. 6 is a schematic diagram illustrating modeling of the wafer temperature control device in the first embodiment.

FIG. 7 is a simulation result of an operation of the wafer temperature control device in the first embodiment.

FIG. 8 is a schematic diagram of a wafer temperature control device according to a second embodiment of the present invention expressed by a state equation.

FIG. 9 is a simulation result of a wafer temperature output from a temperature estimation observer of the second embodiment when a disturbance is input.

FIG. 10 is a schematic configuration diagram of a wafer temperature control device according to a third embodiment of the present invention.

### DESCRIPTION OF EMBODIMENTS

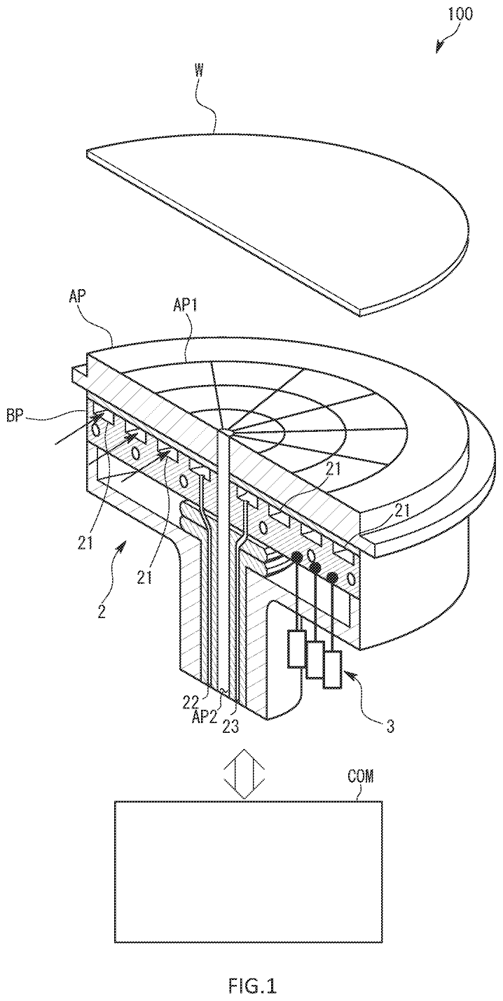

A wafer temperature control device 100 according to a first embodiment of the present invention will be described with reference to FIGS. 1 to 6.

The wafer temperature control device 100 of the present embodiment is configured to electrostatically chuck a back surface of a wafer W in a vacuum chamber, for example. As illustrated in FIG. 1, the wafer temperature control device 100 includes a suction plate AP having a substantially disk shape having the wafer W placed on an upper surface, and a cooler 2 provided so as to be in contact with a lower surface of the suction plate AP.

A surface of the suction plate AP forms a suction surface, and a gas flow groove AP1 for supplying a heat transfer gas is formed between the suction surface and the back surface of the sucked wafer W. For example, helium gas is supplied to the gas flow groove AP1 at a predetermined pressure through the suction plate AP and a vertical through hole AP2 formed along the central axis of the cooler 2. In addition, an electrostatic electrode (not illustrated) for generating electrostatic force between the suction plate AP and the wafer W is embedded in the suction plate AP. Further, a plurality of heater electrodes (not illustrated) for heating the suction plate AP are embedded in the suction plate AP, and these heaters constitute a heater 1. In the present embodiment, a heating amount corresponding to a heating operation amount set by a user is independently output to a heating control unit (not illustrated) connected to each heater electrode. In the present embodiment, the heating amount can be made different between the central portion and the outer peripheral portion of the suction plate AP, and further, the heating amount can be made different between the large region having a substantially C shape in the outer peripheral portion and the remaining small region. That is, three heating regions are set in the suction plate AP.

The cooler 2 includes a base plate BP having a substantially disk shape in contact with a lower surface of the suction plate AP, a refrigerant flow path 21 formed in the base plate BP, and a refrigerant control unit that controls a flow of the refrigerant flowing through the refrigerant flow path 21. The refrigerant flow path 21 forms a spiral shape in the base plate BP, and three cooling regions are formed on the surface of the base plate BP so as to correspond to the three heating regions of the suction plate AP. The inflow of the refrigerant into the refrigerant flow path 21 in the base plate BP or the outflow of the refrigerant from the refrigerant flow path 21 is performed through a refrigerant inflow flow path 22 or a refrigerant outflow flow path 23 formed along the axial direction around the vertical through hole AP2 through which the helium gas flows. Then, the refrigerant flowing in the base plate BP to cool the base plate BP, the suction plate AP, and the wafer W and to be increased in temperature is cooled again by a chiller (not illustrated) provided outside the base plate BP, and circulates through the base plate BP and the suction plate AP and the wafer W. The refrigerant control unit changes the flow of the refrigerant flowing through the refrigerant flow path 21 according to the input cooling operation amount. In the present embodiment, the cooling operation amount is a target cooling amount and is set as a heat quantity, and the refrigerant control unit changes an opening degree of a control valve (not illustrated) that controls the refrigerant flow rate so as to achieve the target cooling amount.

On the back surface side of the base plate BP, temperature measurement is performed by an infrared temperature sensor which is the vicinity temperature measuring instrument 3 for measuring the vicinity temperature of the wafer W. Here, since the temperature measured by the infrared temperature sensor is the temperature of the base plate BP, it is not the temperature of the wafer W itself. In addition, since it is not preferable in various processes and the like to arrange members other than the wafer W in the vacuum atmosphere in the vacuum chamber, the temperature of the wafer W in the vacuum chamber is not directly measured. In the present specification, the vicinity temperature is, for example, a temperature of a member or a space within a predetermined distance from the wafer W, and includes a temperature at which a temperature model indicating a relationship between the wafer temperature and the vicinity temperature can be constructed. Alternatively, the vicinity temperature may include a temperature of a member to which heat conduction or transfer can occur by at least one of conduction, convection, or radiation with the wafer W. More strictly speaking, a temperature of a member in direct contact with the wafer W, a space or gas in which an interface with the wafer W exists, or a member existing with a gap of several um with respect to the wafer W can be defined as the vicinity temperature.

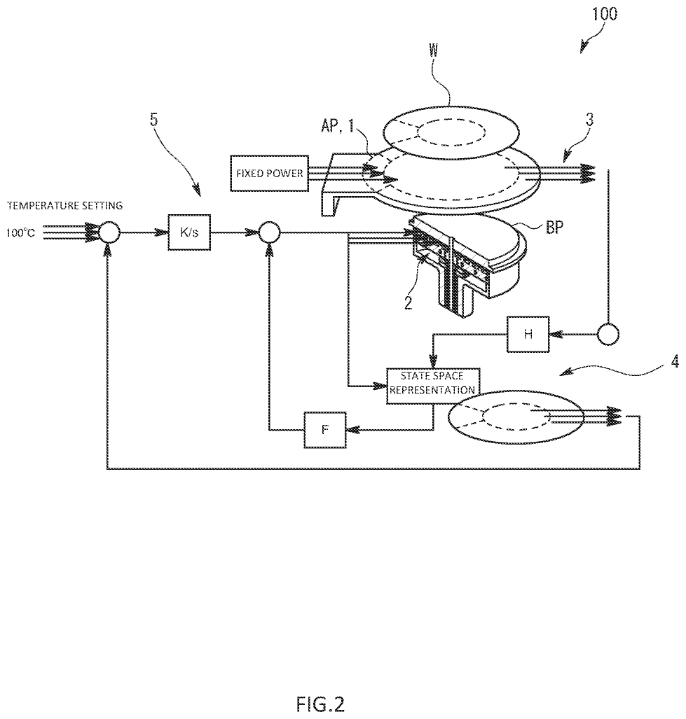

Further, the wafer temperature control device 100 further includes a control device COM that controls at least operations of the heater 1 and the cooler 2, for example, outside the vacuum chamber. The control device COM is a so-called computer including a CPU, a memory, an A/D converter, a D/A converter, and various input/output devices. Then, the program for the wafer temperature control device stored in the memory is executed, and various devices cooperate with each other, whereby a wafer temperature control system as illustrated in FIGS. 2 to 4 is configured.

First, an outline of the wafer temperature control system of the present embodiment will be described with reference to FIG. 2.

In the present embodiment, the fixed power is supplied to each heater electrode constituting the heater 1 regardless of the estimated wafer temperature and the vicinity temperature. That is, the heating operation amount is fixed during the operation, and the heating amount per unit time is controlled to be constant. On the other hand, in the cooler 2, the input cooling operation amount is sequentially changed based on the estimated wafer temperature or the measured vicinity temperature. More specifically, the temperature estimation observer 4 is used to estimate the wafer temperature that cannot be directly measured based on the vicinity temperature measured by the infrared temperature sensor. Furthermore, the estimated wafer temperature and each state variable are fed back, and the cooler 2 is controlled such that the wafer temperature follows the set temperature.

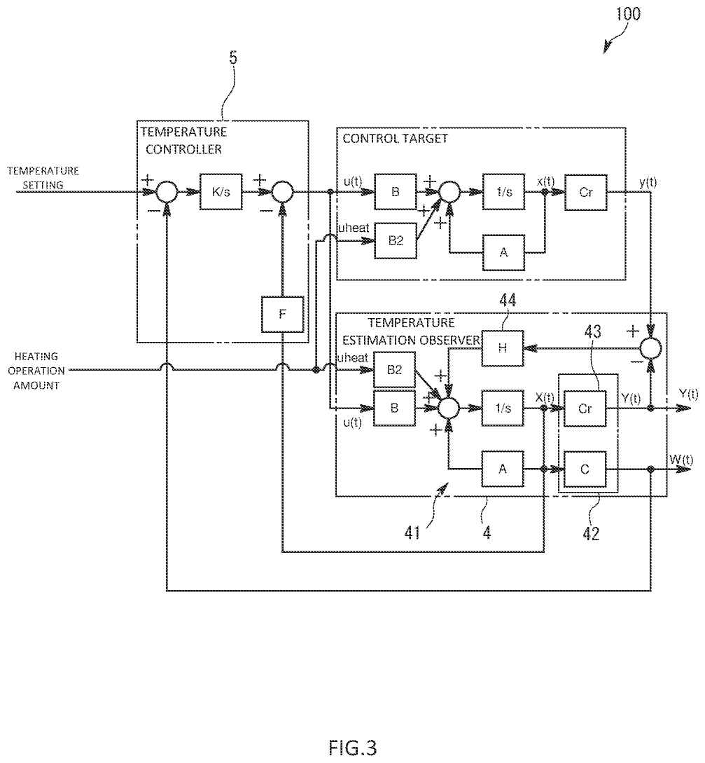

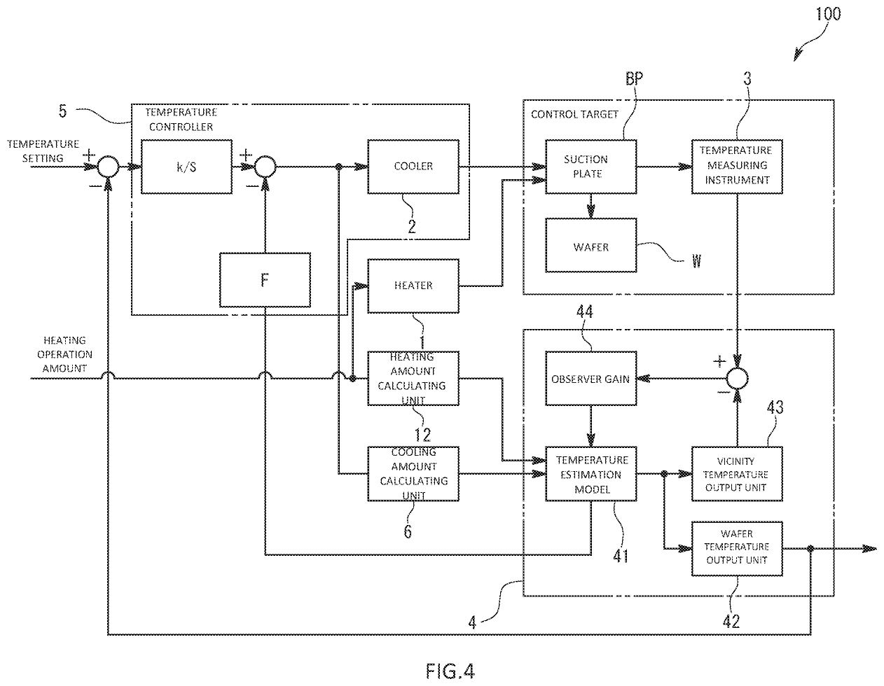

The block diagram of the state space representation related to the wafer temperature control system as illustrated in FIG. 2 is as illustrated in FIG. 3. In addition, FIG. 4 is a functional block diagram illustrating components for implementing each function in detail. That is, the control target in the present embodiment is a heat conduction and heat transfer system including the wafer W and the suction plate AP. The wafer temperature control device 100 exhibits functions as a temperature estimation observer 4 that simulates at least the thermal behavior of the system and estimates the temperature of the wafer W that cannot be directly measured, and a temperature controller 5 that feedback-controls the cooler 2 on the basis of the estimated wafer temperature and various state variables calculated in the temperature estimation observer 4.

As illustrated in FIG. 3, the temperature estimation observer 4 simulates a characteristic of a control target, and outputs an estimated value of a wafer temperature and a vicinity temperature on the basis of a vicinity temperature measured by the vicinity temperature measuring instrument 3 and a cooling amount output from the cooler 2. More specifically, the temperature estimation observer 4 includes a temperature estimation model 41 that is a state space model having a wafer temperature and a vicinity temperature as output variables, a vicinity temperature output unit 43 that outputs the vicinity temperature estimated based on the temperature estimation model 41, a wafer temperature output unit 42 that outputs the wafer temperature estimated based on the temperature estimation model 41, and an observer gain 44. In addition, a value obtained by multiplying a deviation between the estimated value of the vicinity temperature output from the vicinity temperature output unit 43 and the measured value of the vicinity temperature output from the vicinity temperature measuring instrument 3 by the observer gain 44 is fed back into the temperature estimation model 41.

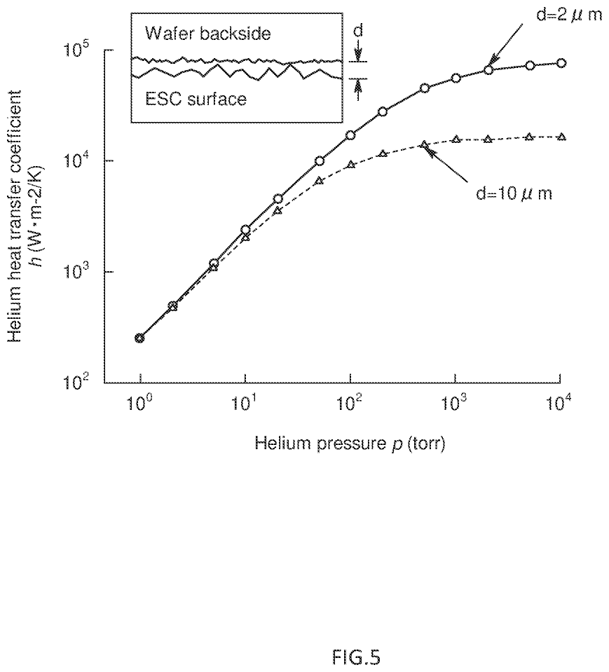

The temperature estimation model 41 models, for example, heat transfer regarding the suction plate AP and the wafer W itself and heat transfer between the suction plate AP and the wafer W. As illustrated in FIGS. 2, 3, and 4, since only the vicinity temperature that is the temperature of the suction plate AP can be actually measured in the control target, the wafer temperature cannot be output from the control target into the control loop. On the other hand, in the temperature estimation observer 4, the wafer temperature can be estimated by calculation on the basis of the temperature estimation model 41 and output into the control loop. An input variable vector u(t) of the temperature estimation model 41 of the present embodiment includes, as an input variable, a cooling amount −q_{gi} which is a heat quantity output from the cooler 2 and taken from the wafer W. Here, the subscript i indicates which of the regions set in the suction plate AP or the wafer W the parameter belongs to, and the same applies to the following description. In this system, the heating amount q_{zi} output from the heater 1 and applied to the wafer W is input as the input variable vector uheat. Since the heating operation amount is fixed in the present embodiment, the heating amount q_{zi} is treated as a fixed value. On the other hand, the cooling amount −q_{gi} is sequentially calculated by a cooling amount calculating unit 6. Specifically, the cooling amount calculating unit 6 determines a heat transfer coefficient h between the wafer W and the suction plate AP on the basis of a model of the heat transfer coefficient h having the pressure p of the helium gas and a separation distance d between the wafer W and the suction plate AP as variables as illustrated in the graph of FIG. 5. Furthermore, the cooling amount calculating unit 6 of the present embodiment is configured to calculate, for example, a value obtained by multiplying the difference between the set temperature of the wafer W and the vicinity temperature by the calculated heat transfer coefficient h as the cooling amount −q_{gi}. Here, the cooling amount −q_{gi} depends on the pressure and flow rate of the helium gas, the temperature difference between the gas and the wafer, and the like, and has complicated characteristics having interaction and nonlinearity due to temperature change. In the present embodiment, such a complicated phenomenon is not modeled as it is, but for the temperature of the wafer W used in the cooling amount calculating unit 6, a fixed value at a set temperature and a function approximated near the temperature are derived to calculate the cooling amount −q_{gi}. In this way, the control system is simplified, and the wafer temperature can be controlled with required accuracy while reducing the calculation load and the like. That is, the cooling amount −q_{gi} is defined as a function −q_{gi}=βi (p) of the pressure p of the helium gas. For example, when the calculation capability is sufficient, the difference Δt between the wafer temperature and the temperature (vicinity temperature) of the suction plate AP may be calculated from the output of the temperature controller 5, and the cooling amount −q_{gi} may be calculated by multiplying Δt by the determined heat transfer coefficient h.

In addition, an output variable vector y(t) in FIGS. 3 and 4 includes a wafer temperature T_{wi} and a vicinity temperature Tₚᵢ, which is the temperature of the suction plate AP, as output variables. The state variable vector x(t) includes, as state variables, the wafer temperature T_{wi} and the vicinity temperature Tₚᵢ that is the temperature of the suction plate AP.

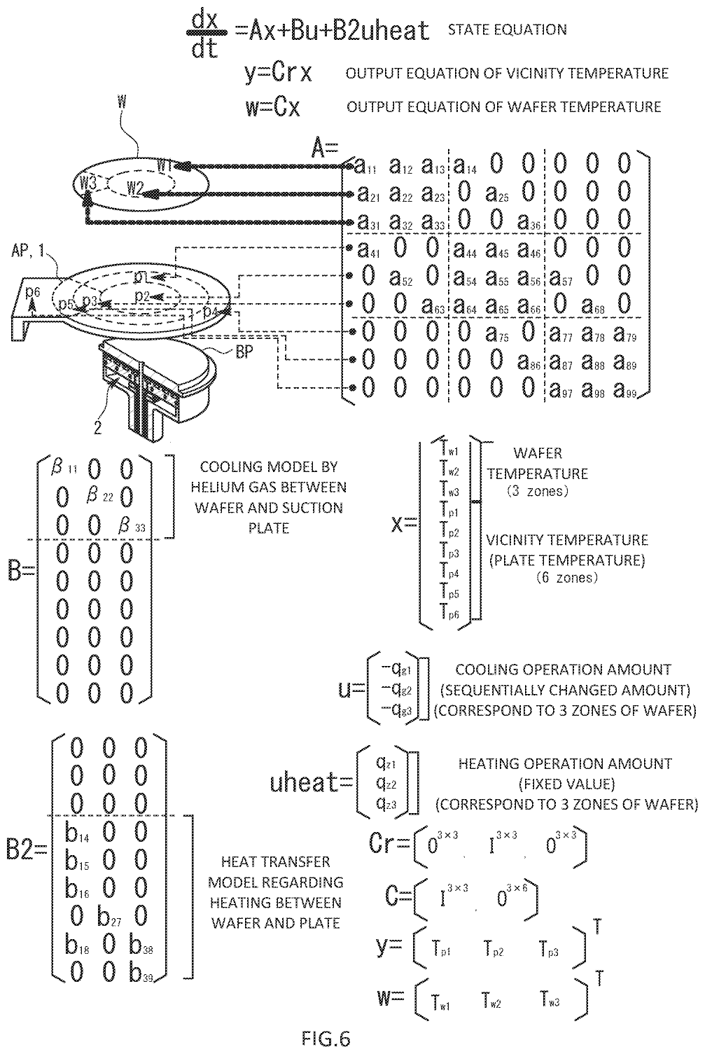

Then, in a case where a state matrix is A, input matrixes are B and B2, and output matrixes are Cr and C, the temperature estimation model 41 is defined by a state equation d/dt (x(t))=Ax+Bu+B2uheat, an output equation y=Crx, and w=Cx as illustrated in FIG. 6. Here, A, B, B2, Cr, and C may be determined based on a heat conduction equation or a heat transfer relational equation, or each element of each matrix may be determined based on an experiment or the like. When an outer peripheral C-shaped region W1, a central region W2, and an outer peripheral fan-shaped region W3 set on the wafer W are set, and a contact C-shaped region P1 in contact with the outer peripheral C-shaped region W1 of the wafer W, a contact central region P2 in contact with the central region W2 of the wafer W, a contact fan-shaped region P3 in contact with the outer peripheral fan-shaped region W3 of the wafer W, a non-contact C-shaped region P4 outside the wafer W and not in contact with the wafer W, a non-contact fan-shaped region P5 outside the wafer and not in contact with the wafer W, and a protrusion region P6 protruding further outward from the non-contact fan-shaped region P5 are set on the suction plate AP, the correspondence relationship between each row of the state matrix A and the actual system is as illustrated in FIG. 6. The elements of each row of the state matrix A are set to values calculated based on, for example, a heat transfer coefficient that determines heat transfer characteristics between the wafer W and the suction plate AP.

In the input matrix B, the cooling characteristic of each region of the wafer W by the helium gas is defined. In the input matrix B2, heating characteristics by the heater electrode are defined. In the present embodiment, since a part of the state variable vector x(t) is extracted as the output variable vector, the output matrixes Cr and C are defined only by the zero matrix and the identity matrix. The state variable vector x(t) is state fed back to the temperature controller 5.

The wafer temperature output unit 42 extracts only an element corresponding to the wafer temperature from the output of the temperature estimation model 41 and outputs the element to the temperature controller 5. For example, the wafer temperature output unit 42 corresponds to the output matrix C.

The vicinity temperature output unit 43 extracts only an element corresponding to the vicinity temperature from the output of the temperature estimation model 41 and outputs the extracted element. A deviation between the output estimated value of the vicinity temperature and the measured value of the vicinity temperature output from the vicinity temperature measuring instrument 3 is calculated and input to the observer gain 44. The vicinity temperature output unit 43 corresponds to an output matrix Cr in the present embodiment.

The temperature controller 5 performs an integration operation by multiplying the temperature deviation between the wafer temperature estimated by the temperature estimation observer 4 and the set temperature by a gain K. In addition, a deviation between the calculated integrated value and a value obtained by multiplying the state variable vector x(t) by a predetermined state feedback gain F is calculated, and this deviation is input to the cooler 2 as a cooling operation amount.

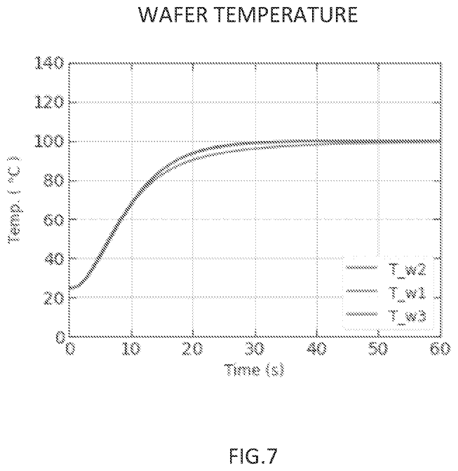

FIG. 7 illustrates a simulation result of the operation when 100° C. is set as the set temperature in the wafer temperature control device 100 configured as described above. According to the wafer temperature control device 100 of the present embodiment, it can be seen that the temperature of each region of the wafer W can be controlled to the set temperature of 100° C. with substantially the same primary delay characteristic on the basis of the wafer temperature estimated by the temperature estimation observer 4.

As described above, according to the wafer temperature control device 100 of the present embodiment, by estimating the wafer temperature that cannot be actually measured by the temperature estimation observer 4 and feeding back the estimated value of the wafer temperature and other state variables, it is possible to keep the wafer temperature that cannot be actually measured at the set temperature.

In addition, since the output of the heater 1 is made constant and the output of the cooler 2 is configured to be temperature feedback-controlled and state feedback-controlled, even when it is desired to maintain the wafer temperature at a high temperature such as 100° C., highly accurate control can be realized almost without causing overshoot or the like.

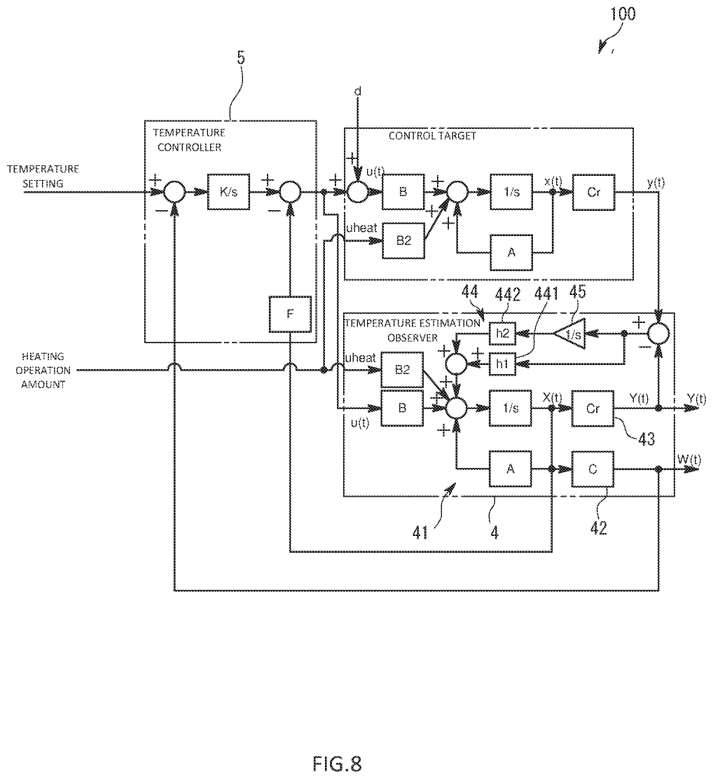

Next, a wafer temperature control device 100 according to a second embodiment of the present invention will be described with reference to FIG. 8. Note that portions corresponding to the portions described in the first embodiment are denoted by the same reference numerals.

The wafer temperature control device 100 of the second embodiment takes into consideration the influence on the temperature estimation observer 4 when the disturbance d is input to the system. The temperature estimation observer 4 of the wafer temperature control device 100 of the second embodiment is different from that of the first embodiment in that an observer integrator 45 is provided. More specifically, in the temperature estimation observer 4, a deviation between the estimated value of the vicinity temperature and the measured value of the vicinity temperature measuring instrument 3 is fed back to the temperature estimation model 41, and an integrated value of the deviation described above is also fed back to the temperature estimation model 41 in parallel.

That is, the temperature estimation observer 4 includes a first feedback loop that feeds back a value obtained by multiplying the deviation between the estimated value and the measured value of the vicinity temperature by a proportional observer gain 441 to the temperature estimation model 41, and a second feedback loop that integrates the deviation between the estimated value and the measured value of the vicinity temperature by the observer integrator 45 and feeds back a value obtained by multiplying the integrated value by an integral observer gain 442 to the temperature estimation model 41. Here, the proportional observer gain 441 and the integral observer gain 442 correspond to the observer gain 44 in the first embodiment.

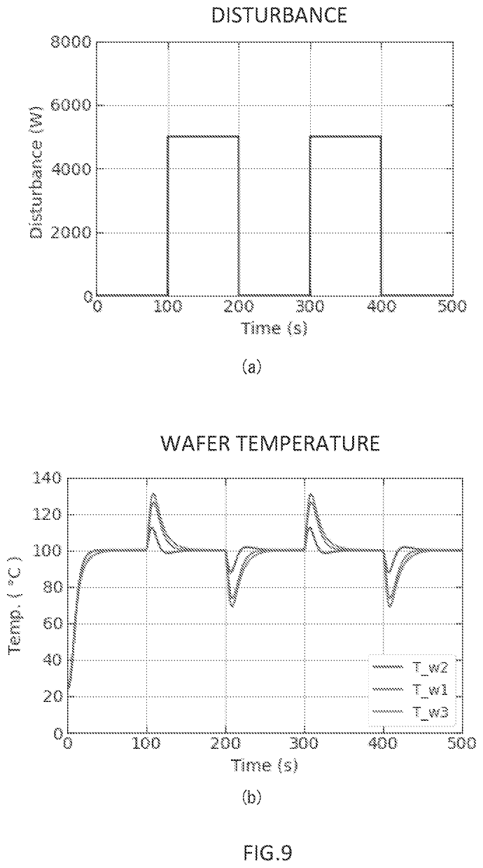

Next, FIG. 9(b) illustrates a simulation result regarding estimation of the wafer temperature by the temperature estimation observer 4 of the second embodiment when a periodic disturbance d occurs as illustrated in FIG. 9(a). Even when the periodic disturbance is input while the wafer temperature is changed from 25° C. to 100° C. and maintained at 100°° C., the estimated value of the wafer temperature and the control result can be converged to the set temperature so as to cancel the disturbance. In other words, in the absence of the observer integrator 45, when a disturbance occurs, the wafer temperature estimated by the temperature estimation observer 4 may continue to have a predetermined deviation from the actual wafer temperature. However, in the second embodiment, such an estimation error can be eliminated, and the actual wafer temperature can be finally estimated even when the disturbance d is input.

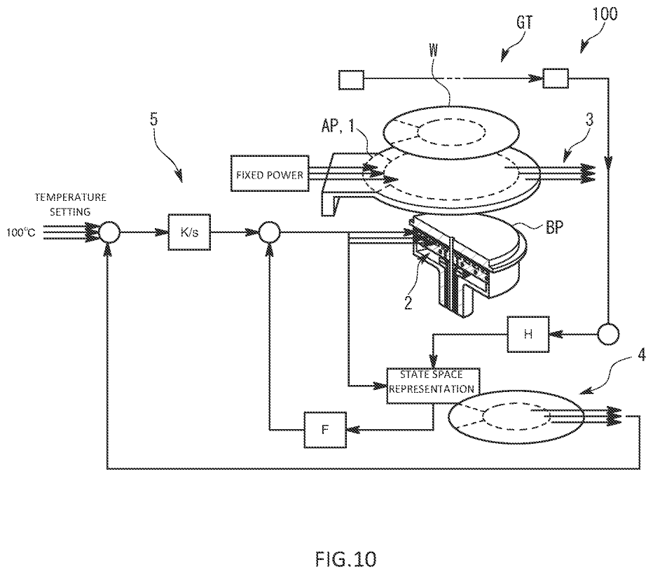

Next, a wafer temperature control device 100 according to a third embodiment of the present invention will be described with reference to FIG. 10. Note that portions corresponding to the portions described in the first embodiment are denoted by the same reference numerals.

The wafer temperature control device 100 of the third embodiment further includes a gas temperature measuring instrument GT that measures the temperature of the gas present near the upper side of the wafer W in the chamber, and the temperature estimation observer is configured to estimate the wafer temperature using not only the vicinity temperature measured by the suction plate AP measured by the radiation thermometer as a measured value but also the gas temperature measured by the gas temperature measuring instrument GT. Here, the gas temperature measuring instrument GT is, for example, a light absorption analyzer configured to measure the gas temperature on the basis of the absorbance of laser light passing immediately above the wafer W along the surface plate direction.

In the wafer temperature control device 100 of the third embodiment, not only the wafer temperature and the vicinity temperature but also the gas temperature can be included in the state vector x used for the temperature estimation model. In addition, only the gas temperature is included as a component in the state vector x of the state equation described in the first embodiment, and other matrixes and vectors can be handled in a similar manner. The estimation accuracy of the wafer temperature estimated based on such a state equation can be improved by the increase in the information on the actually measured temperature, and the control accuracy of the wafer temperature can be further improved.

Other embodiments will be described.

Although the heater is controlled to have a constant output, the heating operation amount of the heater may also be changed by output feedback control or state feedback control.

The temperature estimation observer may be configured as a Kalman filter in consideration of the influence of disturbance. Various existing methods may be used as a method of setting the Kalman gain instead of the observer gain.

The method of calculating the cooling amount used as the input variable is not limited to the modeling method described above. For example, the temperature difference may be calculated as an approximate value assuming that the temperature difference between the wafer and the suction plate is a constant value.

The configuration of the cooler or the heater is not limited to that described above. For example, the cooler may be configured using a Peltier element or the like, and the heater is not limited to the heater electrode, and may be configured to heat the wafer by light irradiation.

The heating or cooling regions of the wafer and the suction plate are not limited to those in which three regions are partitioned, and a larger number of regions may be further partitioned, or two regions may be partitioned. In addition, the entire wafer or the entire suction plate may be handled as one temperature without setting the region. The suction plate may not have a suction function, and may be a plate on which the wafer is simply placed.

The location measured by the vicinity temperature measuring instrument is not limited to the location described above, and may be another location. In short, a temperature that is likely to have some correlation or relationship with the wafer temperature may be measured as the vicinity temperature. The temperature controller is not limited to the infrared temperature sensor, and may be, for example, a thermocouple provided in a plate.

In the second embodiment, the integrated value of the deviation is fed back to the temperature estimation model together with the deviation between the measured value and the estimated value of the vicinity temperature. However, for example, only the integrated value of the deviation may be fed back to the temperature estimation model.

In addition, various modifications and combinations of the embodiments may be made without departing from the gist of the present invention.

### INDUSTRIAL APPLICABILITY

According to the present invention, it is possible to provide a wafer temperature control device capable of accurately estimating the wafer temperature that is difficult to directly measure even when the cooling operation amount is changed, and for example, capable of improving the control accuracy of the wafer temperature as compared with the related art.

### REFERENCE CHARACTERS LIST

100 wafer temperature control device
1 heater
2 cooler
21 refrigerant flow path
3 vicinity temperature measuring instrument
4 temperature estimation observer
5 temperature controller
41 temperature estimation model
42 wafer temperature output unit
43 vicinity temperature output unit
44 observer gain
AP suction plate
BP base plate

1. A wafer temperature control device comprising:
a heater that heats a wafer according to an input heating operation amount;
a cooler that cools the wafer according to an input cooling operation amount;
a vicinity temperature measuring instrument that measures a vicinity temperature of the wafer;
a temperature estimation observer that estimates a wafer temperature on a basis of the vicinity temperature measured by the vicinity temperature measuring instrument and a cooling operation amount input to the cooler or a cooling amount output from the cooler; and
a temperature controller that controls the cooling operation amount so as to reduce a temperature deviation between a set temperature and the estimated wafer temperature.

2. The wafer temperature control device according to claim 1, wherein the temperature estimation observer includes:
a temperature estimation model that is a state space model using the wafer temperature and the vicinity temperature as output variables;
a vicinity temperature output unit that outputs the vicinity temperature estimated based on the temperature estimation model;
a wafer temperature output unit that outputs the wafer temperature estimated based on the temperature estimation model; and
an observer gain, and
a value obtained by multiplying a deviation between an estimated value of the vicinity temperature output from the vicinity temperature output unit and a measured value of a vicinity temperature output from the vicinity temperature measuring instrument or a value calculated from the deviation by the observer gain is fed back into the temperature estimation model.

3. The wafer temperature control device according to claim 2, wherein
the temperature estimation observer further includes an observer integrator that integrates the deviation between the estimated value of the vicinity temperature output from the vicinity temperature output unit and the measured value of the vicinity temperature output from the vicinity temperature measuring instrument, and
a value obtained by multiplying an integrated value output from the observer integrator by the observer gain is fed back into the temperature estimation model.

4. The wafer temperature control device according to claim 1, further comprising a plate on which the wafer is placed, wherein
the heater is configured to heat the plate, and
the cooler is configured to cool the plate.

5. The wafer temperature control device according to claim 4, wherein the cooler includes:
a refrigerant flow path; and
a refrigerant control unit that controls a flow of a refrigerant flowing in the refrigerant flow path, and
the cooling operation amount is a cooling amount or a target refrigerant flow rate of the wafer.

6. The wafer temperature control device according to claim 4, wherein
the temperature estimation model is a state space model in which a heating amount by the heater and a cooling amount by the cooler are input variables and the wafer temperature and the vicinity temperature are state variables, and
the cooling amount is calculated based on a difference between the wafer temperature and the vicinity temperature and a heat transfer coefficient between the wafer and the plate.

7. The wafer temperature control device according to claim 6, wherein
a heat transfer gas is supplied between the wafer and the plate at a predetermined pressure, and
the heat transfer coefficient is calculated based on the pressure of the heat transfer gas.

8. The wafer temperature control device according to claim 1, wherein the heating operation amount is set to a constant value.

9. The wafer temperature control device according to claim 1, wherein the temperature controller is configured to feed back a state variable vector estimated by the temperature estimation observer.

10. The wafer temperature control device according to claim 1, further comprising a gas temperature measuring instrument that measures a temperature of a gas present near an upper side of the wafer, wherein
the temperature estimation observer is configured to estimate the wafer temperature on a basis of the vicinity temperature measured by the vicinity temperature measuring instrument, a cooling operation amount input to the cooler or a cooling amount output from the cooler, and a gas temperature measured by the gas temperature measuring instrument.

11. A control method for a wafer temperature control device including a heater that heats a wafer according to an input heating operation amount and a cooler that cools the wafer according to an input cooling operation amount, the control method comprising:
measuring a vicinity temperature of the wafer;
estimating a wafer temperature on a basis of the vicinity temperature measured by the vicinity temperature measuring instrument and a cooling operation amount input to the cooler or a cooling amount output from the cooler; and
controlling the cooling operation amount so as to reduce a temperature deviation between a set temperature and the estimated wafer temperature.

12. A non-transitory computer readable medium storing a program for a wafer temperature control device, the program being used in a wafer temperature control device including a heater that heats the wafer according to an input heating operation amount and a cooler that cools the wafer according to an input cooling operation amount, the program being executable by a computer to cause the computer to exhibit functions of:
a vicinity temperature measuring instrument that measures a vicinity temperature of the wafer;
a temperature estimation observer that estimates a wafer temperature on a basis of the vicinity temperature measured by the vicinity temperature measuring instrument, and a cooling operation amount input to the cooler or a cooling amount output from the cooler; and
a temperature controller that controls the cooling operation amount so as to reduce a temperature deviation between a set temperature and the estimated wafer temperature.
